(19) United States
(12) Patent Application Publication
(10) Pub. No.: US 2013/0206462 A1
(43) Pub. Date: Aug. 15, 2013

(54) ANISOTROPIC CONDUCTIVE FILM DISPERSED WITH CONDUCTIVE PARTICLES, AND APPARATUS AND METHOD FOR PRODUCING SAME

(71) Applicant: HON HAI PRECISION INDUSTRY CO., LTD., (US)

(72) Inventor: KUO-FONG TSENG, New Taipei (TW)

(73) Assignee: HON HAI PRECISION INDUSTRY CO., LTD., New Taipei (TW)

(21) Appl. No.: 13/714,318

(22) Filed: Dec. 13, 2012

(30) Foreign Application Priority Data
Feb. 14, 2012 (TW) 101104619

(51) Int. Cl. H05K 3/10; H05K 1/02

(52) U.S. Cl. CPC H05K 3/10; H05K 1/0296
USPC 174/257; 118/204; 427/58; 174/250; 174/258

(57) ABSTRACT

An anisotropic conductive film includes a substrate layer, an insulated layer and a number of conductive particles dispersed in the insulated layer. The insulated layer includes a lower layer attached on a side surface of the substrate layer and a nano-structured layer having a number of nano-scaled micro-structures on the lower layer. The conductive particles are dispersed in the nano-structured layer and insulated and spaced from each other by the micro-structures.

### BACKGROUND

1. Technical Field

The present disclosure relates to an anisotropic conductive film, and an apparatus and method for producing the anisotropic conductive.

2. Description of Related Art

Anisotropic conductive films are widely used in liquid crystal displays for electrically connecting driving chips to a liquid crystal panel. The anisotropic conductive films perform an electrical conduction along a thickness direction thereof and an electrical insulation along a planar direction thereof.

An anisotropic conductive film typically includes a substrate layer, an insulated layer formed on a surface of the substrate layer and a plurality of conductive particles dispersed in the insulated layer. When a pressure is applied to an area of the anisotropic conductive film, the conductive particles in the area will puncture the insulated layer, forming a current passage through the anisotropic conductive film. To provide a uniform conductivity, the anisotropic should be uniformly dispersed in the insulated layer. However, in current methods of making the anisotropic conductive film, the conductive particles are randomly dispersed in the insulated layer, thus it is difficult to control the density of the conductive particles in the in the insulated layer. Therefore, a performance of the anisotropic conductive film cannot be ensured.

What is needed therefore is an anisotropic conductive film, and an apparatus and method for producing the anisotropic conductive films addressing the limitations described.

### BRIEF DESCRIPTION OF THE DRAWINGS

The components of the drawings are not necessarily drawn to scale, the emphasis instead being placed upon clearly illustrating the principles of the embodiments of the present disclosure. Moreover, in the drawings, like reference numerals designate corresponding parts throughout several views.

FIG. 1 is a schematic view of an anisotropic conductive film, according to an exemplary embodiment of the present disclosure.

FIG. 2 is a schematic view of an apparatus for producing anisotropic conductive films, according to an exemplary embodiment of the present disclosure.

FIG. 3 is a cross-sectional view of the apparatus of FIG. 2 along line III-III.

FIGS. 4-5 are schematic views showing successive stages of a method for producing anisotropic conductive films, according to an exemplary embodiment of the present disclosure.

### DETAILED DESCRIPTION

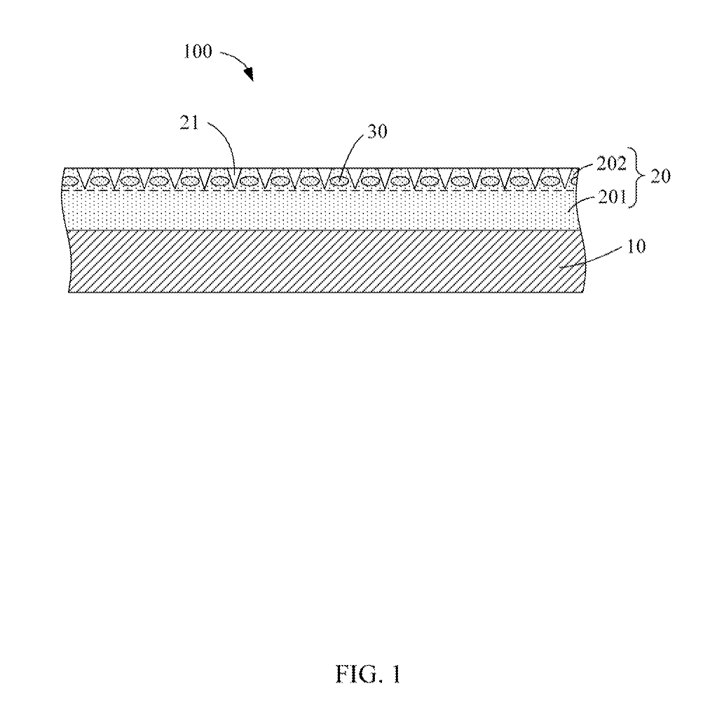

Referring to FIG. 1, an anisotropic conductive film 100, according to an exemplary embodiment, is shown. The anisotropic conductive film 100 includes a substrate layer 10, an insulated layer 20 formed on a side surface of the substrate layer 10 and a number of conductive particles 30 dispersed in the insulated layer 20.

The substrate layer 10 is configured supporting and protecting the insulated layer 20. The substrate layer 10 is made form a flexible insulated material. In this embodiment, the substrate layer 10 is a polyethylene terephthalate (PET) film.

The insulated layer 20 is made from a thermosetting resin. In the embodiment, the insulated layer 20 is epoxy resin. The insulated layer 20 includes a lower layer 201 attached to the substrate layer 10 and a nano-structured layer 202 on the lower layer 201. The nano-structured layer 202 defines a number of nano-scaled micro-recesses 21 on its upper surface. Each of the nano-scaled micro-recesses 21 has a size of less than about 100 nanometers.

The conductive particles 30 dispersed in the nano-structured layer 202. Along the lateral directions substantially parallel to the substrate layer 10, the conductive particles 30 insulatively space the nano-scaled micro-recesses 21. The conductive particles 30 are nano-scaled. The conductive particles 30 are selected from at least one material of the group consisting of nickel, gold, silver and silver-tin alloy.

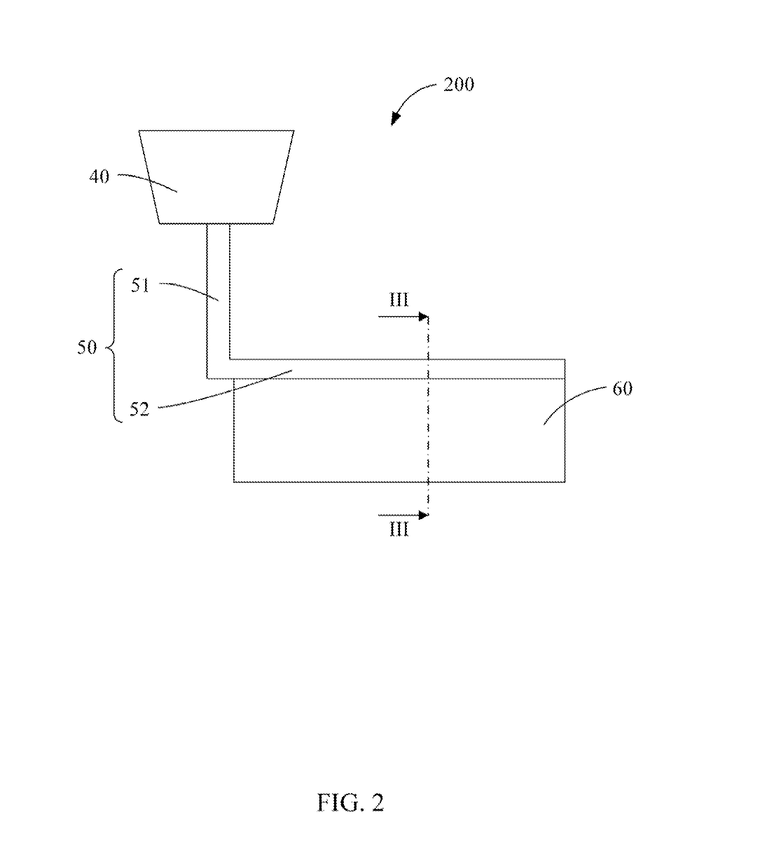

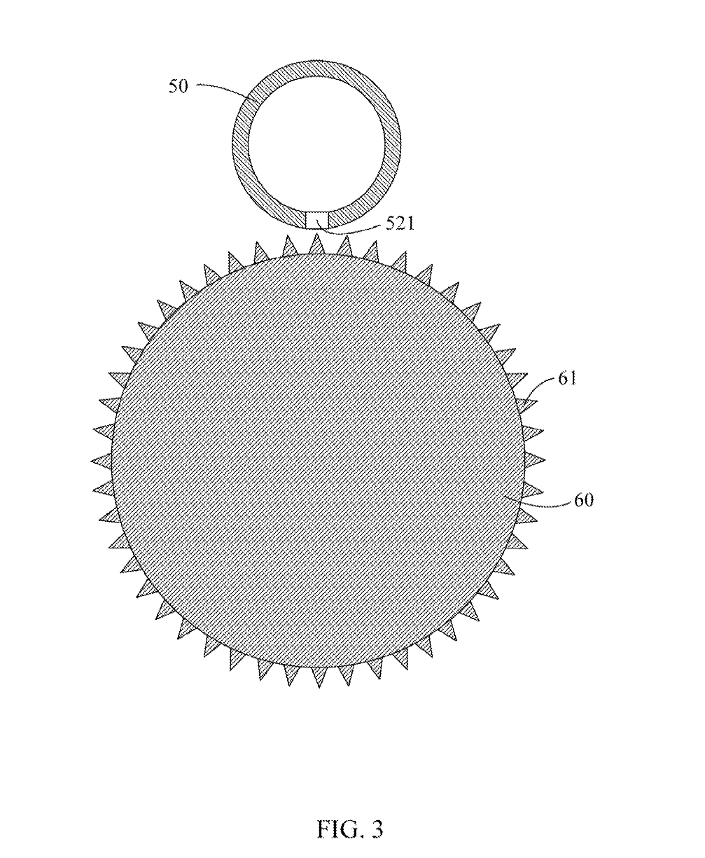

Referring to FIGS. 2-3, an apparatus 200 for producing anisotropic conductive films, according to an exemplary embodiment, is shown. The apparatus 200 includes a glue tank 40, a guiding pipe 50 communicating with the glue tank 40 and a pressing roller 60.

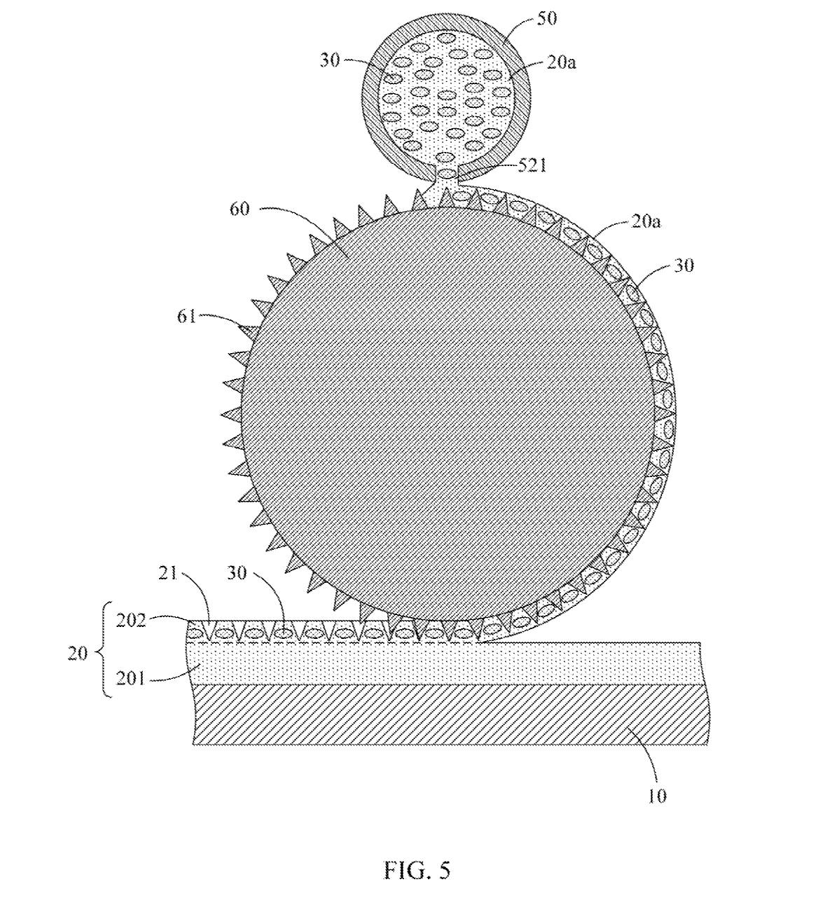

The glue tank 40 is configured for containing liquid insulated glue 20a (referring to FIG. 5) with conductive particles 30 (referring FIG. 5) dispersed therein. To ensure the dispersing uniformity of the conductive particles 30, the insulated glue 20a can be stirred by a stirring device (not shown) after a predetermined period.

The guiding pipe 50 is configured for guiding the insulated glue 20a from the glue tank 40 onto the pressing roller 60. The guiding pipe 50 includes a guiding section 51 and a distributing section 52 connected to the guiding section 51. One end of the guiding section 51 is connected to the glue tank 40, and the other end of the guiding section 51 is connected to the distributing section 52. The distributing section 52 is adjacent to the pressing roller 60, for uniformly distributing the insulated glue 20a onto the pressing roller 60. The distributing section 52 defines a number of through holes 521 allowing the insulated glue 20a flowing therethrough.

The pressing roller 60 is substantially cylinder-shaped. The pressing roller 60 includes a number of nano-scaled micro-protrusions 61. Each micro-protrusion 61 is substantially cone-shaped. A distance between distal ends of two adjacent micro-protrusions 61 is more than a size of the conductive particles 30.

A method for producing anisotropic films, according to an exemplary embodiment, includes the following steps:

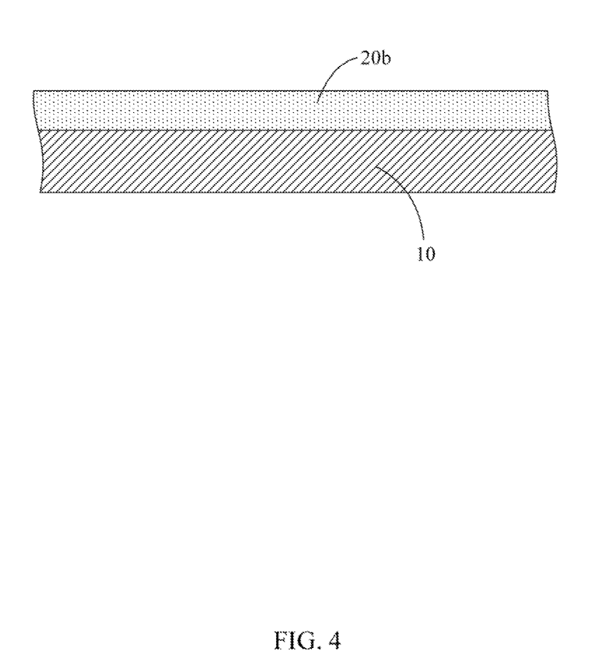

Referring to FIG. 4, a substrate layer 10 is provided. In the embodiment, the substrate layer 10 is a PET film.

An insulated glue 20b is formed on a side surface of the substrate layer 10. In the embodiment, the insulated glue 20b is formed on the substrate layer 10 by a high speed photoresistive coater (not shown). The insulated glue 20b is made from thermosetting resin. In the embodiment, the insulated glue 20b is epoxy resin.

The insulated glue 20b is then heated to be solidified, so as to obtain a lower layer 201 on the substrate layer 10.

Referring to FIG. 5, the apparatus 200 of FIGS. 2 and 3 is provided. The glue tank 40 contains liquid insulated glue 20a with conductive particles 30 dispersed therein, the pressing roller 60 is rotated encircling a central axis thereof. The distributing section 52 uniformly distributes the insulated glue 20a with the conductive particles 30 onto a cylindrical surface of the pressing roller 60, the conductive particles 30 are dispersed between the micro-protrusions 60. A thickness of the insulated glue 20a distributed on the pressing roller 60 is controlled at a predetermined level, in this embodiment, a thickness of the insulated glue 30 is slightly more than the protruding height of the micro-protrusions 60.

The insulated glue 20a is distributed on the lower layer 201 by the pressing roller 60. Because of the micro-protrusions 61 of the pressing roller 60, the conductive particles 30 are restricted by the pressing roller 60, therefore, a uniformity of the conductive particles 30 dispersed in the insulated glue 20a on the lower layer 201 can be easily controlled. The pressing roller 60 also prints a number of micro-recesses 21 corresponding to the micro-protrusions 61 on a surface of the insulated glue 20a on the lower layer 201. Along lateral directions substantially parallel to the substrate layer 10, the conductive particles 30 are insulated spaced from each other by the micro-recesses 21. The insulated glue 20a with the micro-recesses 21 on the lower layer 201 is heated to solidify, so as to form a nano-structured layer 202 on the lower layer 201.

The solidified nano-structured layer 202 and the lower layer 201 constitute an insulated layer 20 of an anisotropic conductive film 100.

Because of the micro-protrusions 61 of the pressing roller 60, during distributing the insulated glue 20a on the lower layer 201, the conductive particles 30 are restricted by the pressing roller 60. Therefore, a uniformity of the conductive particles 30 dispersed in the insulated glue 20a on the lower layer 201 can be easily controlled. Accordingly, a performance of an anisotropic conductive film is ensured.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

1. An anisotropic conductive film, comprising:
a substrate layer;
an insulated layer comprising a lower layer attached on a side surface of the substrate layer and a nano-structured layer, the nano-structured layer having a plurality of nano-scaled micro-structures on the lower layer; and
a number of conductive particles dispersed in the nano-structured layer, the conductive particles insulated and spaced from each other by the micro-structures.

2. The anisotropic conductive film of claim 1, wherein the nano-scaled micro-structures are micro-recesses, along lateral directions substantially parallel to the substrate layer, the conductive particles are insulated and spaced from each other by the micro-recesses.

3. The anisotropic conductive film of claim 1, wherein the substrate layer is a PET film.

4. The anisotropic conductive film of claim 1. wherein a material of the insulated layer is epoxy resin.

5. The anisotropic conductive film of claim 1, wherein the conductive particles are made from at least one material selected from the group consisting of nickel, gold, silver and silver-tin alloy.

6. An apparatus for producing anisotropic conductive films, comprising:
a glue tank for containing liquid insulated glue with conductive particles dispersed therein;
a guiding pipe communicating with the glue tank; and
a pressing roller, the guiding pipe guiding pipe guiding the insulated glue, from the glue tank onto the pressing roller;
wherein the pressing, roller comprises a plurality of nano-scaled micro-protrusions, a distance between distal ends of each two adjacent micro-protrusions is more than a size of the conductive particles.

7. The apparatus of claim 6, wherein the guiding pipe comprises a guiding section and a distributing section connected to the guiding section, one end of the guiding section is connected to the glue tank, and the other end of the guiding section is connected to the distributing section, the distributing section is adjacent to the pressing roller for uniformly distributing the insulated glue onto the pressing roller.

8. The apparatus of claim 7, wherein the distributing section defines a number through holes for allowing the insulated glue to flow therethrough.

9. The apparatus of claim 6, wherein each micro-protrusion is substantially cone-shaped.

10. A method for producing anisotropic conductive films, comprising:
providing a substrate layer
forming a first insulated glue on a. side surface of the substrate layer;
heating the first insulated glue to solidify, so as to obtain a lower layer on the side surface of heating the substrate layer;
providing the apparatus claimed in claim 6;
infusing a second insulated glue with conductive particles dispersed therein into the glue tank,
distributing the second insulated glue with the conductive particles onto the pressing roller through the guiding pipe;
distributing the second insulated glue with the conductive particles on the lower layer using the pressing roller;
printing a number of nano-scaled micro-structures corresponding to the micro-protrusions in a surface of the second insulated glue on the lower layer by using the pressing roller; and
heating the second insulated glue with the micro-structures on the lower layer to solidify, so as to obtain a nano-structured layer on the lower layer.

11. The method of claim 10, wherein the substrate layer is a PET film.

12. The method of claim 10, wherein the lower layer is made from epoxy resin.
